(19) United States
(12) Patent Application Publication
(10) Pub. No.: US 2022/0022553 A1
(43) Pub. Date: Jan. 27, 2022

(54) Electronic Cigarette with Display

(71) Applicant: JT International S.A., Geneva (CH)

(72) Inventors: Peter Uhrmeister, Trier (DE); Michael Plattner, Trier (DE); Aleksandr Kontarev, Trier (DE)

(73) Assignee: JT International S.A., Geneva (CH)

(21) Appl. No.: 17/311,922

(22) PCT Filed: Jan. 31, 2020
(86) PCT No.: PCT/EP2020/052506

§ 371 Date: Jun. 8, 2021

(30) Foreign Application Priority Data
Feb. 6, 2019 (EP) 19155810.5

(51) Int. Cl. A24F 40/60; A24F 40/10; A24F 40/42; A24F 40/65; H01L 27/32; G05B 15/02

(52) U.S. Cl. CPC A24F 40/60; A24F 40/10; A24F 40/42; G05B 15/02; H01L 27/323; H01L 27/3239; A24F 40/65

(57) ABSTRACT

An electronic cigarette has a mouthpiece portion with a liquid store, and a power supply portion with a power source and electrical circuitry. The electronic cigarette has a display configured to display an image; the display is integrated into the housing of the electronic cigarette. The display can be integrated into the housing of the liquid store, and the housing of the liquid store can be at least partially transparent. The display can be at least partially transparent, and can be an OLED display.

### FIELD OF INVENTION

The present invention relates to a display for an electronic cigarette.

### BACKGROUND

Electronic cigarettes and other aerosol inhalers or vaporisation devices are becoming increasingly popular consumer products.

In electronic cigarette products, an aerosol-forming, or vaporisable, substance is stored in a tank in liquid form. The tank typically has an outlet connected to a wicking or fluid transfer element which supplies the aerosol or vapour forming substance to an atomiser. In addition to the fluid transfer element, the atomiser also includes a heating arrangement that vaporises the liquid aerosol or vapour forming substance.

There is a need for modern devices to provide interoperability and allow information to be communicated to a user and provide a more engaging experience. Electronic cigarettes and vaporisation devices are traditionally not well suited to deal with these challenges. An object of the present invention is, therefore, to address such challenges.

### SUMMARY

According to an aspect of the invention, an electronic cigarette is provided, the electronic cigarette comprising housing, a mouthpiece portion and a power supply portion, wherein the mouthpiece portion comprises a mouthpiece and a liquid store, wherein the liquid store has a housing, and wherein the power supply portion comprises a power source and an electrical circuitry; wherein the electronic cigarette further comprises a display having a plurality of light-emitting diodes or pixels configured to display an image, wherein the display is integrated into the housing of the electronic cigarette.

In this way, information can be conveyed to the user by the display, thereby enhancing the user experience.

Preferably, the light emitting diodes are integrated into the housing of the liquid store.

In this way, the display is arranged such that it will not be obscured by the hand of a user when holding the electronic cigarette.

Preferably, the housing of the liquid store is at least partially transparent.

In this way, the user can view both the display and the content of liquid in the liquid store.

Preferably, the display follows the shape of the liquid store.

In this way, the display can be viewed in whichever rotational position the electronic cigarette is being held.

Preferably, the display is at least partially transparent.

In this way, the display does not obscure the user's view into the liquid store. The liquid level and information on the display can be viewed simultaneously.

Preferably, the display layer is a layer arranged on the outside of the liquid store.

Preferably, the light-emitting diodes comprise thin flexible sheets of an organic electroluminescent material.

The thin, flexible sheets of organic electroluminescent material are used to form an OLED (organic light emitting diode) display. OLED displays are advantageous as they provide high image quality levels with high transparency levels.

Preferably, there is a protective layer arranged over the display.

In this way the display can be protected from damage, thereby providing a more hard-wearing and robust device. Preferably the protective layer comprises polycarbonate, polyethylene terephthalate (PET), thermoplastic polyurethane (TPU), or tempered glass.

Preferably, a touch responsive interface is integrated with the display.

In this way, the user can interact with the electronic cigarette. The touch interface is arranged in a position that an easily be reached by a finger or thumb of the user, whilst the display is not being obscured by the user holding the electronic cigarette particularly when the display is arranged on the liquid tank of the electronic cigarette.

Preferably, the display is connected to a controller and is configured for two-way communication, enabling the user to obtain operating information and modify the settings of the electronic cigarette by the touch responsive interface.

In this way, the user can modify operating settings and/or view information using the display; this improves the usability of the electronic cigarette.

Preferably, the display is integrated into the mouthpiece portion and the mouthpiece portion comprises a power supply connector and a data connector configured to be engaged with cooperating connectors on the power supply portion, wherein the mouthpiece portion is removably attached to the power supply portion.

In this way, the display can be powered by the power supply portion whist also allowing the mouthpiece portion to be removable from the power supply portion. A separate power supply is not needed for the display. As such, the heater, display and control electronics/processor can be powered from a single source.

Preferably the display is a layer arranged on an outer surface of the liquid store.

Preferably, the power supply connector and data connector comprise a first plurality of protrusions arranged on the mouthpiece portion and the cooperating connectors on the power supply portion comprise a second plurality of protrusions on the power supply portion, wherein the first plurality of protrusions and second plurality of protrusions are arranged to be in alignment when the mouthpiece portion and power supply portion of the electronic cigarette are in connection.

In this way, power and data connections can be easily achieved between the display and power supply and control electronics/processor when bringing the power supply portion and mouthpiece portion into connection with one another. Preferably, the protrusions are pogo pins.

Preferably, the display presents at least one of: a battery charge status, a coil temperature, a power setting, a number of remaining puffs, information relevant to the device, a device status, information relevant to a consumable.

In this way, useful information can be presented to the user, thereby improving the user experience.

Preferably, display information is stored as a program in a memory of the electrical circuitry and the electrical circuitry further comprises a communication module configured receive information to modify the program on the memory.

In this way the software and operating programmes on the electronic cigarette can be updated or modified using an external device, such as a smart phone, tablet or computing device. The electronic cigarette, therefore, does not need to locally house the processing capabilities required for updating, modifying or installing the software/operating programmes as this is controlled by an external device.

Preferably, the communication module is a means for wired communication.

In this way, the electronic cigarette can be connected to a wide variety of devices. Preferably the means for wired communication is a USB port. More preferably the means for wired communication is a USB-C port.

Preferably, the communication module is a means for wireless communication.

In this way, the electronic cigarette can be connected to a wide variety of devices and the user is not required to use a cable. The user can instead utilise the wireless communication capabilities of, for example, a smart phone to communicate with the electronic cigarette at any time. This allows for a smart phone to promptly relay information, such as messages, to the electronic cigarette for display. Preferably the means for wireless communication is a Bluetooth transmitter/receiver.

### BRIEF DESCRIPTION OF THE DRAWINGS

Embodiments of the invention are now described, by way of example, with reference to the drawings, in which:

FIG. 1 shows a side view of an electronic cigarette according to embodiments of the invention;

FIGS. 2A to 2F show examples of display information according to embodiments of the invention;

FIG. 3 is a cross-sectional diagram of a liquid tank with a display layer according to embodiments of the invention;

FIG. 4 is a block diagram of components of an electronic cigarette in an embodiment of the invention;

FIGS. 5A and 5B show cross-sectional diagrams of a connection arrangement between a liquid store and a main body of an electronic cigarette according to embodiments of the invention;

FIGS. 6A to 6C show diagrams of a human hand interacting with an electronic cigarette according to embodiments of the invention;

FIG. 7 shows a cross-sectional diagram of a liquid tank with a display layer and a protective layer according to embodiments of the invention;

FIG. 8 shows a tobacco vaporisation device according to embodiments of the invention; and

FIG. 9 shows a device that vaporises liquid from a capsule according to embodiments of the invention.

### DETAILED DESCRIPTION

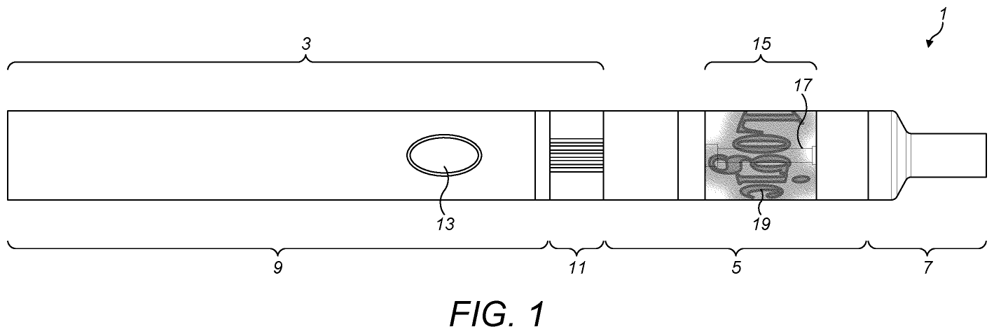

FIG. 1 shows an electronic cigarette 1 having a main body 3, a liquid store 5 and a mouthpiece 7.

The main body 3 contains a battery portion 9 and an atomizer portion 11. The battery portion 9 contains a battery for providing power to the electronic cigarette 1 and control electronics for controlling the operation of the electronic cigarette 1. The atomizer portion 11 contains an atomizer, or heater, arranged to heat and vaporize a vaporizable liquid in the liquid store 5. A user operable button 13 may be further included for functions such as switching the electronic cigarette 1 on and off, and engaging a heater to vaporise a vaporisable liquid in the liquid store.

The liquid store has a liquid tank 15 arranged to contain the vaporisable liquid and a vapour tube 17 extending through the centre of the liquid tank 15, in an axial direction, arranged to transport vapour from the atomizer or heater to the mouthpiece 7. The liquid store 5 engages the atomizer portion 11 at a first end, and the mouthpiece 7 at a second end, wherein the first and second ends of the liquid store are opposite one another. The liquid store 5 may be detachable from the atomizer portion 11 of main body 3 and/or the mouthpiece 7 so that the liquid tank 15 in the liquid store 5 can be filled (or refilled) with a vaporisable liquid.

The mouthpiece 7 is arranged such that when the vaporisable liquid is vaporised by the atomizer or heater it can be inhaled through the mouthpiece 7 by a user by way of the vapour tube 17. The mouthpiece 7 and liquid store 5 combined can be considered a mouthpiece portion of the electronic cigarette. The atomizer portion 11 and battery portion 9 combine can be considered a main body 3 of the electronic cigarette 1.

The electronic cigarette 1 may have a circular cross-section such that the liquid tank 15 has one continuous sidewall. Alternatively, the electronic cigarette 1 can have a non-circular cross section such that the liquid tank 15 has more than one sidewall. Preferably a display 19 is arranged on the sidewall(s) of the liquid tank 15. The sidewall(s) of the liquid tank 15 may be transparent or semi-transparent and a display 19 is arranged on this transparent or semi-transparent portion. Preferably, the display 19 is an organic light emitting diode (OLED) display comprising a plurality of OLEDs. OLED displays are especially preferred due to the brightness and image quality associated with the technology, and their ability for use in transparent displays. This allows for the user to view both the liquid stored in the liquid tank 15, and information presented on the display 19, simultaneously. Arranging the display 19 on the liquid tank 15 allows the user to view the display 19 whilst holding the electronic cigarette by the main body 3 without their hand obscuring the display 19. Alternatively, the display 19 can be an electroluminescent display, an e-ink (or electronic ink) display, an LCD display, a display comprising electrochromic materials, or any other suitable type of display. In some embodiments, where the display technology used obscures the view into the liquid tank due to, for example, a low transparency in the components of the display, the display can be arranged as a grid or matrix in which areas of the liquid tank sidewall are alternately arranged with and without display elements thereon. In this way, an image can be displayed across an array of display elements, whilst also allowing visibility of the liquid in the liquid tank between the elements.

The display 19 wraps around the shape of the liquid tank 15. Alternatively, the display can be arranged on one or more sides of a liquid tank.

Information displayed on the display 19 is customisable by the user to communicate or share text messages, emojis, colour patterns, pictures and photographs and other content to the user and their environment.

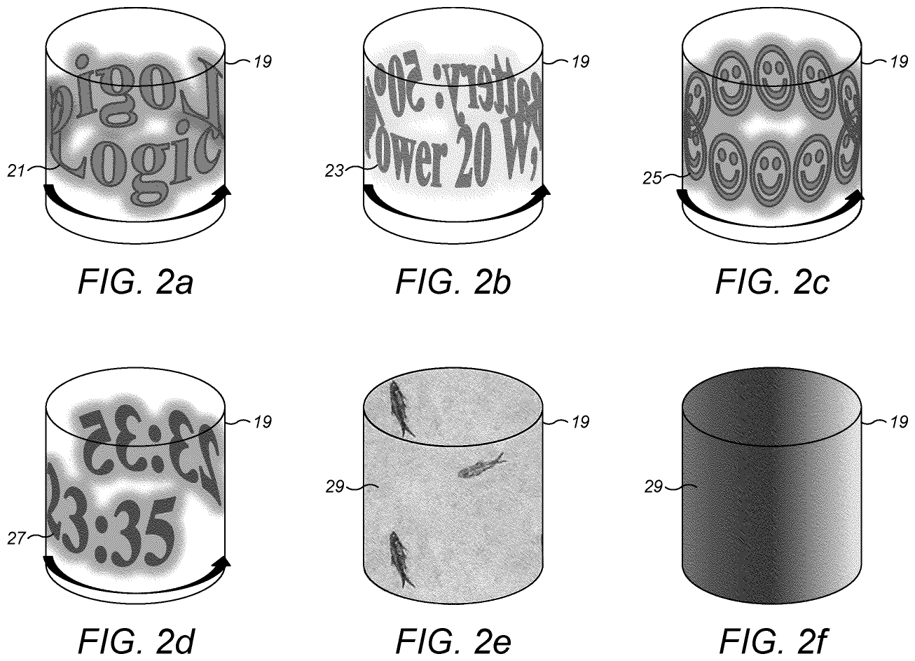

FIGS. 2A to 2F show various examples of information that can be displayed on the display 19.

As shown in FIG. 2A, textual information 21 such as messages or brand information can be displayed on the display 19.

As shown in FIG. 2B, device status information 23 such as a power level applied to the heater, a battery level, a remaining number of puffs, the heater or coil temperature, information relevant to the device, information relevant to a consumable or the like can be displayed on the display 19.

As shown in FIG. 2C, social information 25 such as symbols and emojis can be displayed on the display 19.

Added value content can be displayed on the display 19, such as a clock, a calendar, or information such as text messages transmitted over a Bluetooth interface. As shown in FIG. 2D, information such as the time of day 27 can be displayed on the display 19.

As shown in FIGS. 2E and 2F, the information displayed on the display 19 can be a screensaver or wallpaper 29.

The information displayed on the display 19 can be set to rotate around the display, or to remain static with respect to the electronic cigarette, as appropriate. For example, when there are larger amount of information on the display it may be more useful for this information to rotate so that all of the information is viewable by the user without the user needing to physically rotate the electronic cigarette 1.

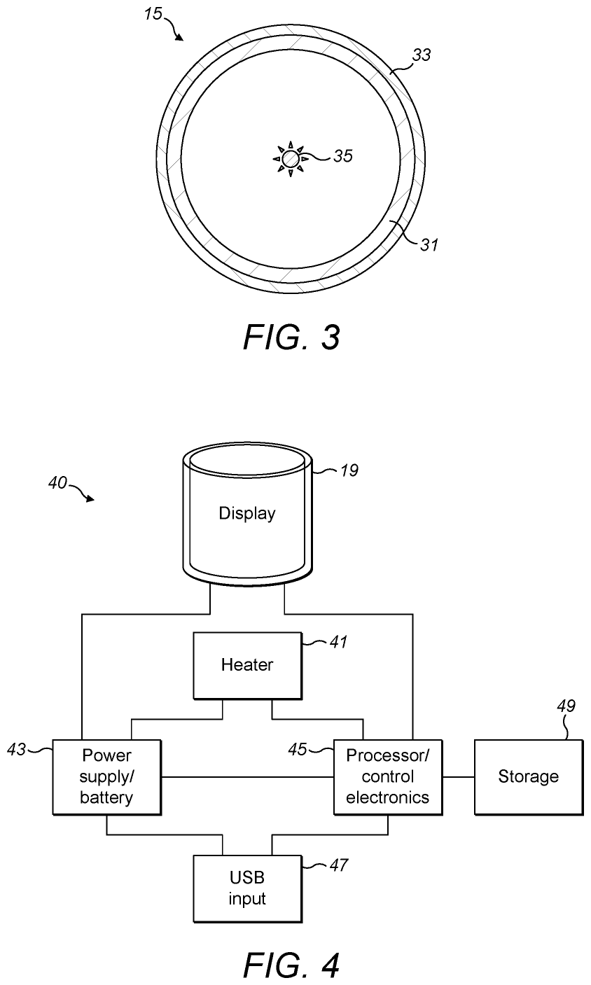

FIG. 3 is a conceptual cross-sectional diagram cut in a direction perpendicular to the axial direction of the liquid tank showing the arrangement of the display 19 on the sidewall(s) 31 of the liquid tank and an optional backlight source 35.

A transparent, or semi-transparent, OLED layer 33 is arranged on an external side of the liquid tank sidewall(s) 31; that is, a side of the sidewall(s) 31 opposite a liquid-facing side of the sidewall(s) 31 inside the liquid tank 15.

For clarity only the sidewall(s) 31, the OLED layer 33 forming the display, and the optional backlight source 35 are shown. The skilled person would however understand that the liquid tank 15 would further include the vapour tube 17 as shown in FIG. 1. In an example, the backlight source 35 may be arranged along the length of the vapour tube 17. In another example the backlight source may be arranged on an upper and/or lower rim of the tank. In another example a transparent light-emitting foil can be arranged under the OLED layer 33. The backlight source may provide improved visibility and legibility of information presented on the display.

FIG. 4 shows a block diagram 40 of the arrangement of the power and control electronics for the display. The display is connected to a processor, controller, or control electronics, 45 by a data connection and to a power supply 43, such as a battery, by a power connection.

The processor 45 controls the information displayed on the display 19 by sending data to the display 19 by way of a data in connection. The data, or programmes, are stored in memory 49 in the main body 3 of the electronic cigarette 1 and accessed by the processor 45 for directing to the display 19. Alternatively, or additionally, the data can be received over a wired connection 47 (such as USB) or a wireless connection (such as Bluetooth) and downloaded to the memory 49; the received data such as text or images can then be directed to the display 19 by the processor 45, or stored locally in the storage 49. In embodiments where the display 19 includes touch screen functionality, the processor receives and processes data from the touch screen display 19, by way of a data out connection, corresponding to touch interactions; that is, a two-way communication is present between the display 19 and processor 45. The data connections operate by any suitable standard data protocols. The user can obtain operating information and modify settings of the electronic cigarette by viewing the display 19 and providing touch inputs by the display 19 being in communication with the processor 45.

The power supply 43 to the display is provided by the battery housed in the battery portion 9 of the electronic cigarette 1. Preferably the same battery 43 is used to power the atomizer/heater 41 and the display 19, as well as the processor 45. In embodiments which include a backlight 35, the backlight is also powered by the same battery 43.

The electronic cigarette 1 includes a connection for receiving data and power from an external source by a single wired connection 47. Such a means is provided by a USB port 47 in the electronic cigarette 1. This allows for the electronic cigarette 1 to receive programming information, such as programmes and data for display, and also for the battery 43 to be charged by a USB wired connection 47. Preferably the USB port is a USB-C port. Alternatively, the electronic cigarette can be arranged to work with micro-USB, nano-USB, Lightning and other such connections as the wired connection 47.

In further examples, the electronic cigarette 1 may be able to receive data from an external source by wireless connection means such as Bluetooth, WiFi, near-field communication (NFC) or the like. In a specific example, the user can interface the electronic cigarette 1 over a Bluetooth connection with another device such as a mobile telephone such that text messages (or other media and/or communications) received by the mobile telephone can be displayed by the electronic cigarette. In another example, pictures and photographs transferred to the mobile telephone over the Bluetooth connection can be displayed.

The programming information, such as programmes and data, received by the wired or wireless connection can be stored in the storage and can be used to modify existing programming information stored in the storage.

In some examples the battery 43 electronic cigarette 1 may be configured to be charged by induction charging.

The processor 45 and the power supply, or battery, 43 are housed in the main body 3 of the electronic cigarette, and preferably in the battery portion 9. The storage 49 is also be housed in the main body 3, and preferably in the battery portion 9. The USB port 47, or any other wired or wireless communication means are housed in the main body 3, and preferably in the battery portion 9.

The heater is housed in the main body 9, and preferably in the atomizer portion 11. The display 19 is arranged as part of the liquid store 5. In other embodiments, the processor and storage can be housed in the mouthpiece portion.

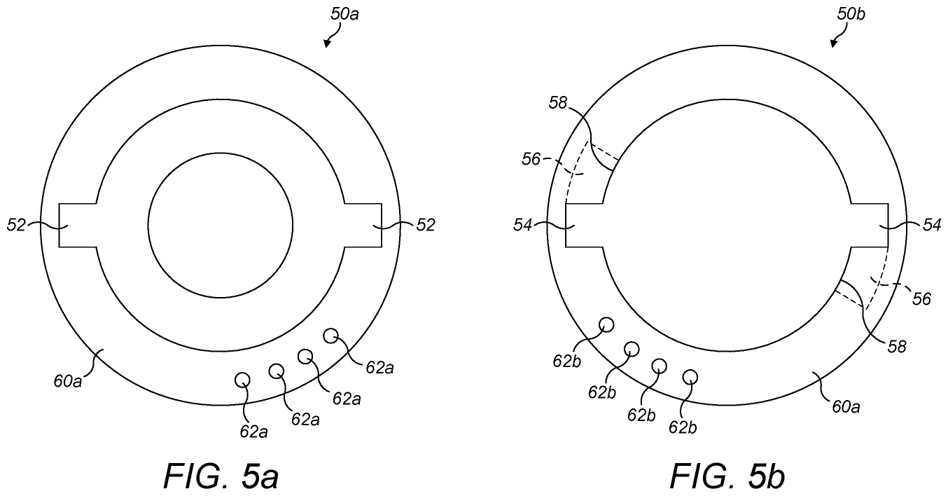

The liquid store 5 is preferably detachable from the main body 3. FIGS. 5a and 5b show diagrams of the connecting portions 50a, 50b of the liquid store 5 and the main body 3 of the electronic cigarette 1 respectively.

The liquid store 5 can be connected to the main body 3 by a bayonet connection. That is, tabs 52 on the liquid store 5 engage with slots 54 on the main body 3 (or vice versa) such that when the liquid store 5 is rotated with respect to the main body 3 the liquid store 5 becomes secured to the main body 3 in a locked position wherein the tabs 52 are misaligned from the slots 54 and secured in place by abutment under a lip 58 in a groove 56. The liquid store 5 can then be rotated in the opposite direction such that it can be released from the main body 3 in an unlocked position wherein the tabs 52 and slots 54 are re-aligned by the tab passing out from the groove 56 under the lip 58, such that the tab 52 can move out of the slot 54.

Power and data connections are provided between the liquid store and the main body by way of terminals 62a arranged on a surface 60a of the liquid store 5 that abuts the main body 3 upon engagement between the two, and corresponding terminals 62b on a surface 60b of the main body 3 that abuts the liquid store 5 upon engagement between the two. The terminals 62a of liquid store 5 are arranged such that they are brought into alignment and contact with the corresponding terminals 62b of the main body 3 when the liquid store 5 is engaged with the main body 3 and rotated to the locked position. In an example in which the main body 3 has a battery portion 9 and an atomizer portion 11, the connecting portion of the main body is arranged on a surface of the atomizer portion 11 that faces the liquid store 5.

Alternatively, the bayonet connection may be replaced by a threaded connection wherein the liquid store 5 has an internally threaded cavity and the main body 3 has an externally threaded projection (or vice versa) arranged to engage one another such that the liquid store 5 is secured to the main body 3 by rotating the liquid store 5 relative to the main body 3 in a screw-like manner. In this arrangement, the terminals of liquid store 5 are arranged such that they are brought into alignment and contact with the corresponding terminals of the main body 3 when the liquid store 5 is engaged with the main body 3 and rotated to an end point of the threads such that the threads are fully engaged with one another.

In an example, the terminals 62a, 62b are protrusions projected outwardly from both of the surface 60a of the liquid store and the surface 60b of the main body. More specifically the terminals 62a, 62b are resilient in the axial direction of the electronic cigarette 1. For instance, the terminals 62a, 62b can be configured as pogo pins. In this way, each terminal 62a, 62b applies a force to the opposite corresponding terminal 62a, 62b and displaces it inwardly to the liquid store 5 or main body 3 respectively. The resilience of the pogo pin biases outward from the liquid store 5 or main body 3 respectively against this displacement. This results in a secure connection between the terminals 62a, 62b of the liquid store 5 and main body 3 as they are biased toward one another.

In an example there may be four terminals on each of the liquid store 5 and main body 3, corresponding to a positive power terminal, a negative power terminal, a data in terminal and a data out terminal. Additional terminals may also be present for further functionality. In another example, there may only be two terminals on each of the liquid store 5 and the main body 3, corresponding only to a positive power terminal and a negative power terminal for power supply.

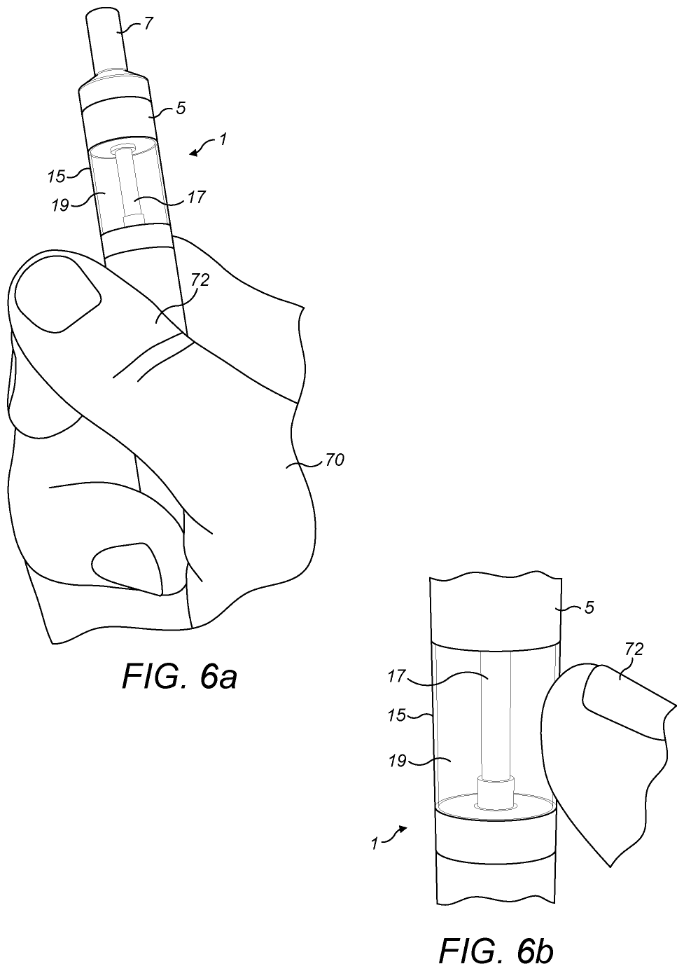

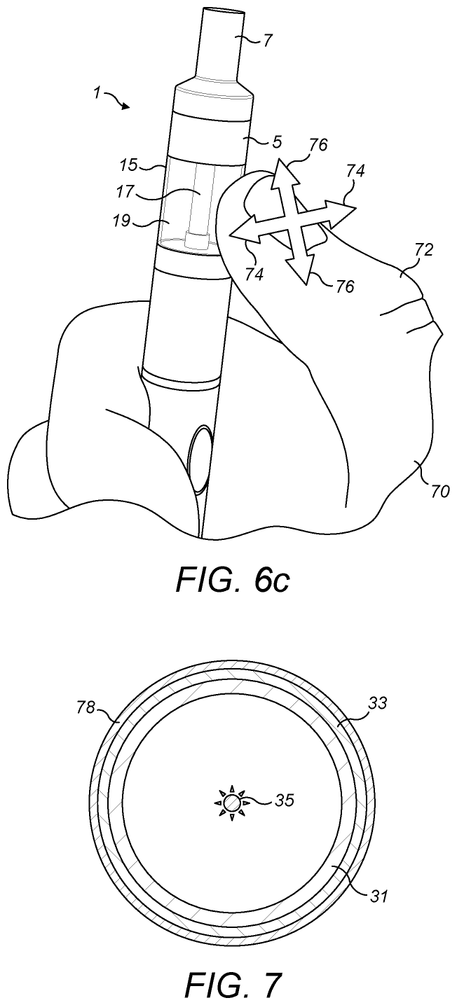

FIGS. 6A to 6C show the electronic cigarette 1 in the hand 72 of a user. In some embodiments, the display 19 of the electronic cigarette includes touch screen capabilities.

The main body 3 may have a minimum diameter of 10 mm and a minimum length of 90 mm. The liquid tank 15 of the liquid store 5 has a cylindrical shape, with a length between 10 mm and 100 mm, a diameter between 10 mm and 50 mm, and a sidewall 31 thickness of 5 mm or less.

In this way the user is able to hold the main body 3 of the electronic cigarette 1 without part of their hand 70, such as a finger or thumb 72, obscuring the liquid tank 15 and the display 19 thereon, as shown in FIG. 6A. Moreover, this arrangement allows for the user to easily reach across a full height of the display 19 with their thumb or finger 72 when holding the electronic cigarette 1; this allows the user to interact with a touch screen integrated in the display 19 with the use of only a single hand 70, as shown in FIGS. 6B and 6C.

The touch screen display 19 may be a resistive touch screen, a surface acoustic wave touch screen, a capacitive touch screen, or any other suitable type of touch screen technology. The touch screen layer is arranged on top of the OLED layer 33 of the display 19. As such, the liquid tank 15 is arranged such that the OLED layer 33 is on top of an external side of the sidewall(s) 31 of the liquid tank 15, and the touch screen layer is on top of the OLED layer 33; that is, the OLED layer 33 is sandwiched between the sidewall(s) 31 of the liquid tank 15 and the touch screen layer.

The electronic cigarette 1 can be programmed to recognise and respond to tapping and swiping gestures input to the touch screen. For example, taps could include short taps (wherein the user touches the display and then quickly withdraws their finger or thumb), long taps (wherein the user brings their finger or thumb into contact with the display and maintains the contact for a longer time period than the short tap, before withdrawing their finger or thumb), two-dimensional swipe gestures (wherein the user brings their finger or thumb into contact with the display and drags it across the display in the x-direction 74, y-direction 76 or a combination thereof), or pinch gestures (wherein the user applies two digits to the display and moves them toward or away from one another).

Example operations in response to various taps or swipes can include:
Locking and unlocking the electronic cigarette with a predetermined number of taps on the display, for example 5 taps;
Locking and unlocking the electronic cigarette with long or multiple taps;
Adjusting the heating power level of the heater with short taps (the display may then show the new power level for a predetermined period of time);
Adjusting the heating power level of the heater with short swipes, for example in the in the x or y-direction (the display may then show the new power level for a predetermined period of time);
Adjusting display settings, such as brightness and contrast, with short taps in menus or submenus;
Adjusting the display settings, such as brightness and contrast, with short swipes in menus or submenus;
Activating a content menu with a short or long tap;
Activating a content menu with a swipe;
Navigating a menu by swiping in the x-direction and/or the y-direction;
Navigating a menu with short taps on a specifically designated area of the display; and
Selecting menu items with a short long tap.

A navigational progression through the menu may for example present the user in turn with a clock, the power level, the remaining battery power, locally stored content such as images, and emojis.

The touch screen display 19 detects the x-y coordinates of a tap on the touch screen display 19. These coordinates are relayed to the processor 45 which determine a response to the tap. If a swiping gesture is input, the touch screen display 19 detects the coordinates through which the swipe has moved. These coordinates are then relayed to the processor 45. The processor 45 determines the gesture from the coordinates.

The processor 45 determines the swipe gestures by analysing the path of the coordinates moved through in the x and y directions 74, 76 and maps these onto known gestures stored in a local database, for example in the storage 49.

For example a movement through coordinates substantially in the y-direction 76 (parallel to the axis of the liquid tank) from the end of the liquid tank 15 proximal to the main body 3, and to the end of the liquid tank 15 proximal to the mouthpiece 7, would be mapped to a gesture in which the user is vertically swiping along the length of the touch screen display 19 toward the mouthpiece 7 (i.e. an ‘upward swipe’).

A movement through coordinates substantially in the y-direction 76 but from the end of the liquid tank 15 proximal to the mouthpiece 7, and toward the end of the liquid tank 15 proximal to the main body 3, would be mapped to a gesture in which the user is vertically swiping along the length of the touch screen display 19 away from the mouthpiece 7 (i.e. a ‘downward swipe’).

A movement through coordinates of increasing value in substantially the x-direction 74 (perpendicular to the y-direction) would be mapped onto a gesture in which the user is swiping from the leftward side of the touch screen display 19 toward a rightward side of the touch screen display 19 (i.e. a ‘right swipe’).

A movement through coordinates of decreasing value in substantially the x-direction 74 would be mapped onto a gesture in which the user is swiping from the rightward side of the touch screen display 19 toward a leftward side of the touch screen display 19 (i.e. a ‘left swipe’).

In some embodiments the display 19 has a protective layer 78. FIG. 7 shows a conceptual cross-sectional diagram cut in a direction perpendicular to the axial direction of the liquid tank 15 showing the arrangement of the display 19 on the sidewall(s) 31 of the liquid tank 15, and a protective layer 78 deposited over the OLED display 33. An optional backlight source 35 is also shown. For clarity only the sidewall(s) 31, OLED layer 33, protective layer 78 and backlight source 35 are shown. The skilled person would however understand that the liquid tank 15 would further include the vapour tube 17 as shown in FIG. 1. In an example, the backlight source 35 may be arranged along the length of the vapour tube 17.

The protective layer 78 forms a cover over the transparent, or semi-transparent, OLED layer 33 to protect it from damage by, for example, impact. As is shown in FIG. 7, the OLED layer 33 is sandwiched between the sidewall 31 of the liquid tank 15 and the protective layer 78. That is, in the outward direction from the liquid tank 15, layers are arranged in the order of the sidewall 31, the OLED layer 33 and then the protective layer 78.

In embodiments where the display 19 further comprises touch screen capability, the protective layer 78 is arranged over the touch screen layer, which itself is arranged over the OLED layer 33. That is, in the outward direction from the liquid tank, layers are arranged in the order of the sidewall 31, the OLED layer 33, the touch screen layer and then the protective layer 78.

The protective layer 78 preferably comprises polycarbonate, polyethylene terephthalate (PET), thermoplastic polyurethane (TPU), or tempered glass. Any other suitable protective layers may also be used.

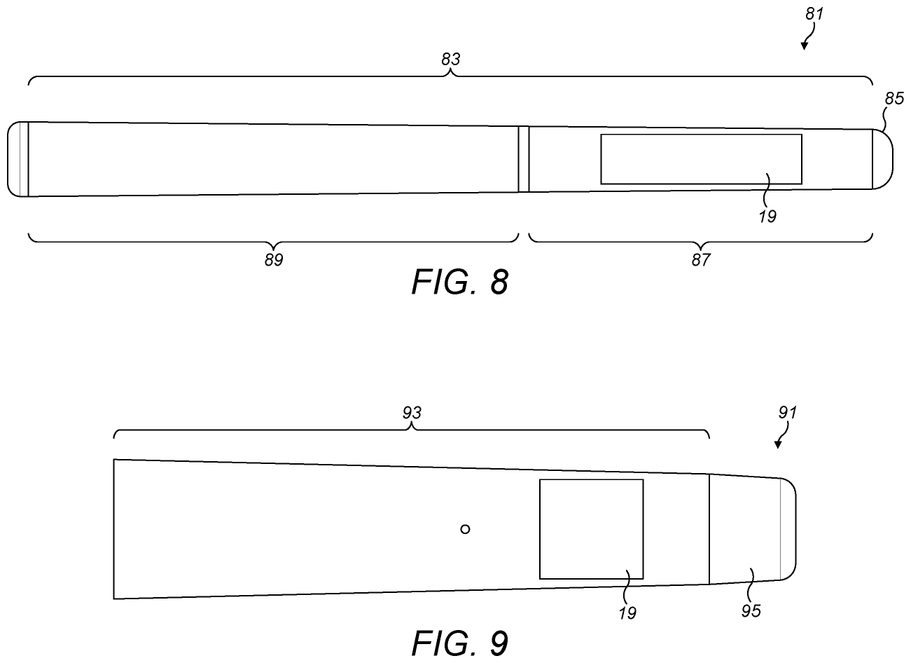

In the other embodiments, for example those presented in FIGS. 8 and 9, a display 19 according to the preceding description can be located on the main body of other vaporisation devices.

FIG. 8 shows the display 19 on the main, re-usable, body 83 of a device 81 suitable for the vaporisation of tobacco. The main body 83 of the device 81 has a heater portion 87 with a battery portion 89 connected at a first distal end. A consumable tobacco capsule 85 is received in a second distal end of the heater portion 87 opposite the first distal end. The battery portion 89 includes a battery which provides power to a heater in the heater portion 87. The heater portion 87 is operable to vaporise tobacco in the tobacco capsule 85. The tobacco capsule 85 is arranged such that the user can inhale the vaporised tobacco through the capsule 85. Preferably the display 19 is arranged on the heater portion 87 of the main body 83. In this way the user can view the display 19 with no obstruction from their hand when holding the device 81 by the battery portion 89. Moreover, if the display 19 includes the aforementioned touch screen capabilities, the touch screen display 19 is arranged in a position that can easily be reached by a finger or thumb of the user when holding the device 81 by the battery portion 87. This display 19 is arranged on one side of the device 81; however the display 19 could be arranged on multiple sides or wrapped around the device 81.

FIG. 9 shows the display 19 on the main, re-usable, body 93 of a device 91 suitable for the vaporisation of liquid contained in a consumable liquid capsule 95 received in a distal end of the device 91. The main body 93 of the device 91 has a battery and heater; the battery is arranged to provide power to the heater, and the heater is arranged to vaporise a liquid within the liquid capsule 95 to generate a vapour. The user can then inhale the generated vapour through the capsule 95. Preferably the display 19 is arranged toward the end of the main body 93 at which the capsule 95 is received. In this way the user can view the display 19 with no obstruction from their hand when holding the device 91 toward the opposite end of the main body 93. Moreover, if the display 19 includes the aforementioned touch screen capabilities, the touch screen display 19 is arranged in a position that can easily be reached by a finger or thumb of the user when holding the device 91 toward the end of the main body 93 opposite the end at which the capsule 95 is received. This display 19 is arranged on one side of the device 91; however the display 19 could be arranged on multiple sides or wrapped around the device 91.

Any of the features described with reference to FIGS. 1 to 7 can be included in the embodiments of FIGS. 8 and 9, where appropriate.

In some embodiments, the display can extend substantially the full length of the electronic cigarette or vaporisation device.

1. An electronic cigarette comprising a mouthpiece portion and a power supply portion, wherein the mouthpiece portion comprises a mouthpiece and a liquid store, wherein the liquid store has a housing, and wherein the power supply portion comprises a power source and an electrical circuitry;
wherein the electronic cigarette further comprises a display having a plurality of light-emitting diodes or pixels configured to display an image;
wherein the display is integrated into the mouthpiece portion and wherein the mouthpiece portion comprises a power supply connector and a data connector configured to be engaged with cooperating connectors on the power supply portion, wherein the mouthpiece portion is removably attached to the power supply portion.

2. The electronic cigarette of claim 1, wherein the plurality of light emitting diodes or pixels are integrated into the housing of the liquid store.

3. The electronic cigarette of claim 2, wherein the housing of the liquid store is at least partially transparent.

4. The electronic cigarette of claim 1, wherein the display follows the a shape of the liquid store.

5. The electronic cigarette of claim 1, wherein the display is at least partially transparent.

6. The electronic cigarette of claim 5, wherein the plurality of light-emitting diodes or pixels comprise flexible sheets of an organic electroluminescent material.

7. The electronic cigarette of claim 1, further comprising a protective layer arranged over the display.

8. The electronic cigarette of claim 1, wherein a touch responsive interface is integrated with the display.

9. The electronic cigarette of claim 8, wherein the display is connected to a controller and is configured for two-way communication, enabling a user to obtain operating information and modify settings of the electronic cigarette by the touch responsive interface.

10. The electronic cigarette of claim 1, wherein the power supply connector and the data connector comprise a first plurality of protrusions arranged on the mouthpiece portion and the cooperating connectors on the power supply portion comprise a second plurality of protrusions on the power supply portion, wherein the first plurality of protrusions and the second plurality of protrusions are arranged to be in alignment when the mouthpiece portion and the power supply portion of the electronic cigarette are in connection.

11. The electronic cigarette of claim 1, wherein the display presents at least one of: a battery charge status, a coil temperature, a power setting, a number of remaining puffs, information relevant to the device, a device status, and information relevant to a consumable.

12. The electronic cigarette of claim 1, wherein display information is stored as a program in a memory of the electrical circuitry and wherein the electrical circuitry further comprises a communication module configured to receive information to modify the program on in the memory.

13. The electronic cigarette of claim 12, wherein the communication module is a means for wired communication.

14. The electronic cigarette of claim 12, wherein the communication module is a means for wireless communication.

15. The electronic cigarette of claim 14, wherein the means for wireless communication uses at least one of Bluetooth, WiFi, or near-field communication.

16. The electronic cigarette of claim 12, wherein the communication module is a Bluetooth transmitter/receiver.

17. The electronic cigarette of claim 12, wherein the communication module is a USB port.

18. The electronic cigarette of claim 12, wherein the communication module is a USB-C port, a micro-USB port, a nano-USB port, or a lightning cable port.
